(19) United States
(12) Patent Application Publication
(10) Pub. No.: US 2007/0085179 A1
(43) Pub. Date: Apr. 19, 2007

(54) Automotive plastic lead frame sensor

(75) Inventor: Stephen R. Shiffer, Xenia, OH (US)

Correspondence Address: Kris T. Fredrick;Honeywell International Inc., 101 Columbia Rd., P.O. Box 2245, Morristown, NJ, 07962, US

(73) Assignee: Honeywell International Inc.

(21) Appl. No.: 11/200,351

(22) Filed: Aug. 8, 2005

(51) Int. Cl. H01L 23/495

(52) U.S. Cl. 257/677

(57) ABSTRACT

A plastic lead frame, electrical component system, and method using plastic-injection, plating, and known photolithography techniques are disclosed. The plastic lead frame and electrical component system operates with an integrated circuit, which functions as a sensor, such as an automotive gear tooth sensor. The plastic lead frame includes electrical contacts that serve as a linkage between the sensor and at least one electrical power source. In addition, the plastic lead frame may be constructed from granular or pelletized raw plastic or recycled components.

### TECHNICAL FIELD

Embodiments are generally related to the manufacture of integrated circuit (IC) sensors, particularly plastic lead frames, electrical component systems, and methods. Embodiments are further related to automotive sensors, such as, for example, gear tooth sensor devices. Embodiments are additionally related to plastic injection molding, plating, and photolithography.

### BACKGROUND

Lead frames serve as the ‘backbone’ of integrated circuit components throughout the manufacturing process. Current implementations of lead frame systems employ stamped or etched metal. The cost of raw metallic alloys, processing, and assembly are having a dramatically negative impact in the automotive sensor market and elsewhere.

Plastic lead frames provide an alternative solution to traditional stamped or etched metal lead frames, in that they are cheaper to manufacture, require less time to produce, and offer a higher degree of precision which can be more readily tailored to individual customers' needs.

Circuit layout modifications can now be accomplished within one day using this new innovation, compared to conventional stamped metal lead frames, which can take up to several weeks or even months to complete.

The plastic lead frames are manufactured by initially heating raw plastic materials (typically in a granular or pelletized form) until liquefied. These raw plastic materials may comprise recycled plastic components, such as inoperative plastic lead frames, thus supporting environmental initiatives. Using a plastic-injection molding machine, the liquefied plastic is infused into a pressurized mold of the customer-specified lead frame. Once cooled until hardened, the plastic lead frame is then removed from the mold and ready for the remaining steps in the manufacturing process.

After the plastic lead frame is formed, it is plated with a chemical substance, often metallic in nature, to insure effective bonding and conductivity. Finally, the desired circuit layout is projected onto the plastic lead frame using photolithographic techniques well-established in the art, and the integrated circuit is inspected for quality assurance before implementation.

As previously noted, current implementations of lead frames involve stamping or etching metallic components into a desired configuration. Referring to FIG. 1, a depiction 100 illustrating a plan view of an example of prior art is shown, wherein the metallic lead frame 120 is used in conjunction with an integrated circuit 110. This new design, employing plastic lead frames, seeks to reduce the production time, manufacturing costs, and environmental impact of current metallic lead frame components. Additionally, plastic lead frames offer higher precision, greater functionality, and are dramatically easier to modify.

### BRIEF SUMMARY

The following summary of the invention is provided to facilitate an understanding of some of the innovative features unique to the present invention and is not intended to be a full description. A full appreciation of the various aspects of the invention can be gained by taking the entire specification, claims, drawings, and abstract as a whole.

It is, therefore, one aspect of the present invention to provide for a plastic lead frame and electrical component system.

It is another aspect of the present invention to provide for improved sensing devices and applications.

It is a further aspect of the present invention to provide for a plastic-injected lead frame configured as an electrical linkage between an integrated circuit functioning as an automotive gear tooth sensor and external electronic components including a power source.

It is an additional aspect of the present invention to provide for improved lead frame manufacturing applications.

The aforementioned aspects of the invention and other objectives and advantages can now be achieved as described herein. A plastic lead frame and electrical component system is disclosed, which comprises an integrated circuit functioning as a sensor, and a plastic lead frame including electrical contacts formed thereon and operating as a linkage between the sensor and at least one external electrical power source.

### BRIEF DESCRIPTION OF THE DRAWINGS

The accompanying figures, in which like reference numerals refer to identical or functionally-similar elements throughout the separate views and which are incorporated in and form a part of the specification, further illustrate the present invention and, together with the detailed description of the invention, serve to explain the principles of the present invention.

FIG. 2 illustrates a plan view of a plastic lead frame used in conjunction with an integrated circuit which can be implemented in accordance with a preferred embodiment;

FIG. 2 further illustrates a plastic injection point, which can be adapted for use in accordance with a preferred embodiment;

FIG. 3 depicts a flow chart illustrating the manufacturing process employed in producing a plastic lead frame in conjunction with an integrated circuit.

FIG. 4 illustrates a typical plastic-injection molding machine used to manufacture a plastic lead frame;

### DETAILED DESCRIPTION OF THE INVENTION

The particular values and configurations discussed in these non-limiting examples can be varied and are cited merely to illustrate at least one embodiment of the present invention and are not intended to limit the scope of the invention.

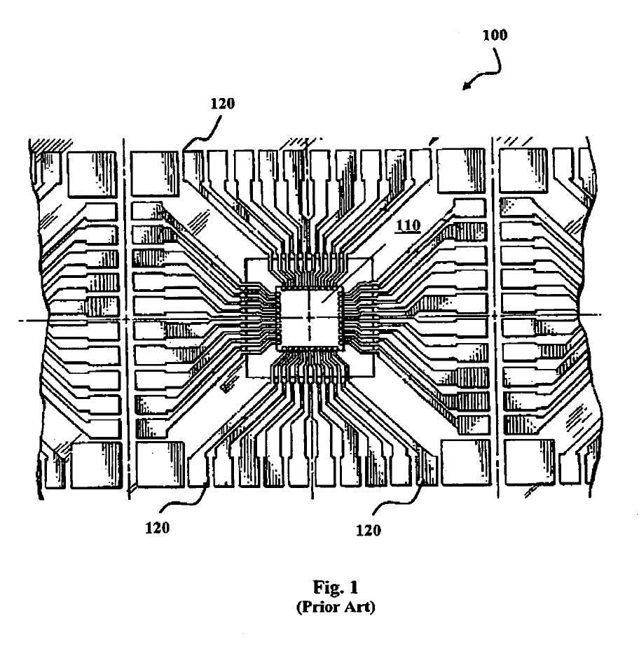

Referring to FIG. 2, a depiction 200 illustrating a plastic lead frame 210 connected to an integrated circuit 220 functioning as a sensor, which can be implemented in accordance with a preferred embodiment is shown. The plastic lead frame 210 was engineered to customer-driven specifications. Note that the plastic lead frame 210 depicted in FIG. 2 is described herein for illustrative purposes only and is not considered a limiting feature of the embodiments. Instead, plastic lead frame 210 is provided in order to depict the context in which one embodiment can be implemented.

Further illustrated by FIG. 2 is a plastic injection point 230, which can be adapted for use in accordance with a preferred embodiment. The plastic injection point 230 facilitates the formation of the plastic lead frame 210, by providing an external fill location, whereby the liquefied plastic materials are poured and/or injected into the desired plastic lead frame mold and allowed to harden. The placement of the plastic injection point 230 as depicted in FIG. 2 is illustrative only and may be modified or varied, depending upon design considerations, and could include the implementation of multiple plastic injection points 230. Additionally, the geometric shape of the plastic injection point 230 can also be modified or varied.

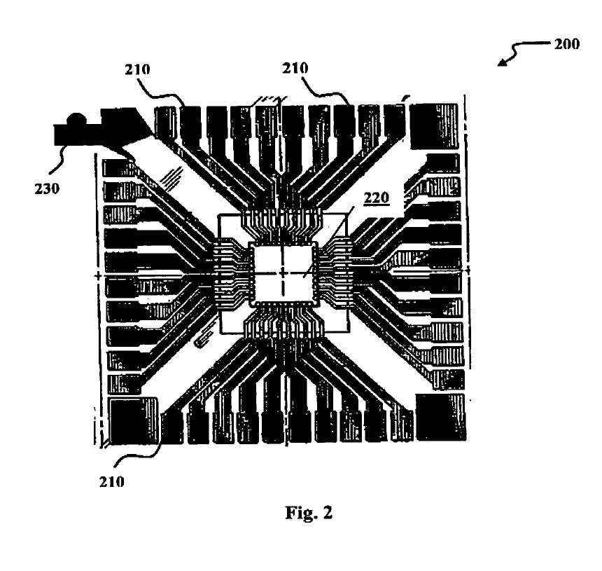

Referring to FIG. 3, a flow chart 300 illustrating the manufacturing process employed in producing a plastic lead frame in conjunction with an integrated circuit is shown.

The first step in the production of the plastic lead frame utilizes raw or recycled plastic (polymer) materials in a granular or pellet form as shown in block 310. Granular or pelletized materials are used in part because of the ability to precisely control the flow of injection and also to facilitate consistency among the melted plastic.

Once the granular or pelletized raw materials are poured into the plastic-injection molding machine, the material is heated at a high temperature (typically 400-500 degrees Fahrenheit) until liquefied as shown in block 320. The liquefied plastic material is then injected into a highly pressurized lead frame mold and is allowed to cool until the plastic lead frame is solidified as shown in block 330. Once hardened, the plastic lead frame is removed from the mold and prepared for additional processing. Prototypes of plastic lead frames can be manufactured using this process within one day.

The newly molded plastic lead frame must then be plated with a conductive material such as Nickel, Gold, Copper, and/or Palladium as shown in block 340. This plating process can be implemented in a variety of configurations, such as spot, selective, and complete plating to accommodate customer needs. Both electrolytic and non-electrolytic plating methods can be used either in combination or individually to complete this step.

Lastly, the desired circuit layout is projected onto the plastic lead frame and circuit using photolithography as shown in block 350. A “photomask” is a plate with an emulsion of metal film with the desired circuit layout located on one side. The mask is aligned with the plastic lead frame and circuit, so that the desired pattern can be transferred onto the surface. Once the photomask has been accurately aligned with the desired pattern on the surface of the plastic lead frame and circuit, a previously deposited photoresist is exposed through the pattern on the photomask with a high intensity ultraviolet light.

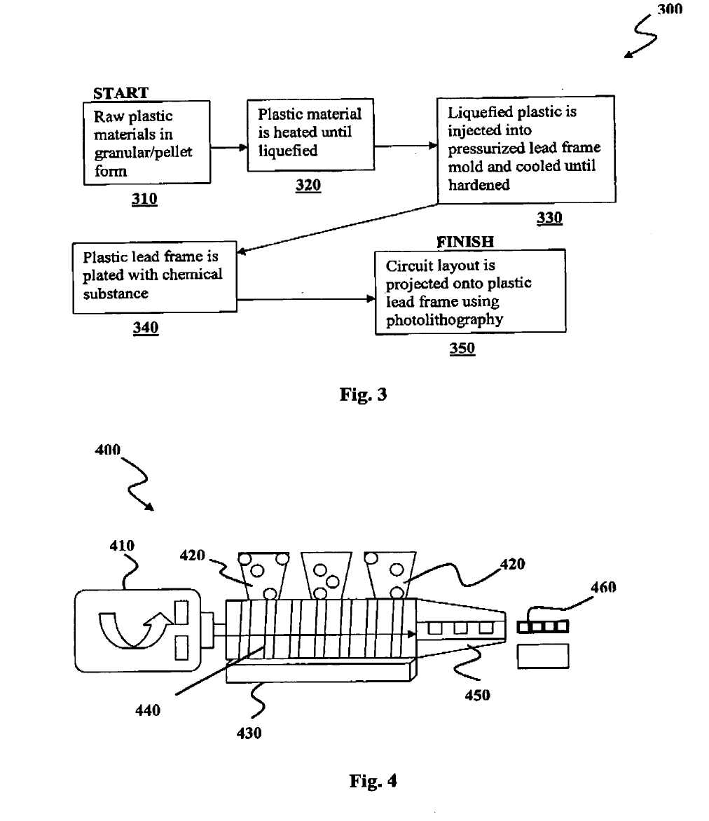

Referring to FIG. 4, a depiction 400 illustrating a typical plastic-injection molding machine is shown. The plastic-injection machine 400 is actuated by a motor 410, which turns an auger 440 that mixes the raw plastic materials (in a granular or pellet form) which were fed into the plastic-injection machine by multiple hoppers 420. While in the plastic-injection machine, the raw plastic materials are liquefied by a heater 430 and subsequently injected into a plastic lead frame mold 450. Once cooled, the finished plastic lead frames 460 are ejected from the machine and ready for additional processing as described in FIG. 3.

It is contemplated that the use of the present invention can involve components having different characteristics. It is intended that the scope of the present invention be defined by the claims appended hereto, giving full cognizance to equivalents in all respects.

1. A plastic lead frame and electrical component system comprising:
an integrated circuit functioning as a sensor; and
a plastic lead frame including electrical contacts formed thereon and operating as a linkage between said sensor and at least one external electrical power source.

2. The plastic lead frame and electrical component system of claim 1, wherein said plastic lead frame includes at least one electrically conductive connector for linking at least part of said sensor to the at least one external power source.

3. The plastic lead frame and electrical component system of claim 1, wherein said integrated circuit is configured as an automotive gear tooth sensor and wherein said plastic lead frame device includes at least one electrically conductive connector for linking at least part of said sensor to the at least one external power source.

4. The plastic lead frame and electrical component system of claim 1, wherein said plastic lead frame device is configured such that the inner lead bonding site of said plastic lead frame is bonded to an electrically conductive input/output terminal on said integrated circuit sensor.

5. The plastic lead frame and electrical component system of claim 1, wherein said plastic lead frame includes a plurality of leads and wherein said leads operate as a linkage between said sensor and the at least one external electrical power source.

6. The plastic lead frame and electrical component system of claim 1, wherein said plastic lead frame is a plastic-injected device and wherein said plastic lead frame device includes at least one connector for linking at least part of said sensor to the at least one external power source.

7. The plastic lead frame and electrical component system of claim 1, wherein said plastic lead frame device is a plastic-injected device and wherein said integrated circuit is configured as an automotive gear tooth sensor and wherein said plastic lead frame device includes at least one electrical connector for linking at least part of said sensor to the at least one external power source.

8. An electrical component system comprising:
an integrated circuit functioning as an automotive gear tooth sensor; and
a plastic-injected lead frame configured as an electrical linkage between said automotive gear tooth sensor and external electronic components including a power source.

9. The electrical component system of claim 8, wherein said plastic-injected lead frame Includes at least one electrical connector for linking at least part of said automotive gear tooth sensor to the at least one external power source.

10. The electrical component system of claim 8, wherein said plastic-injected lead frame is configured such that the inner lead bonding site of said plastic-injected lead frame is bonded to an electronic input/output terminal on said automotive gear tooth sensor.

11. The electrical component system of claim 8, wherein said plastic-injected lead frame includes a plurality of leads and wherein said leads operate as a linkage between said automotive gear tooth sensor and the at least one external electrical power source.

12-17. (canceled)
